(19) United States
(12) Patent Application Publication
(10) Pub. No.: US 2019/0006450 A1
(43) Pub. Date: Jan. 3, 2019

(54) METHOD OF MANUFACTURING A SEMICONDUCTOR ELEMENT, ORGANIC LIGHT EMITTING DISPLAY DEVICE INCLUDING A SEMICONDUCTOR ELEMENT, AND METHOD OF MANUFACTURING AN ORGANIC LIGHT EMITTING DISPLAY DEVICE

(71) Applicants: Samsung Display Co., Ltd., Yongin-si (KR); Industry-Academic Cooperation Foundation, Yonsei University, Seoul (KR)

(72) Inventors: Sunhee Lee, Seoul (KR); Hyungjun Kim, Seoul (KR); Jun Hyung Lim, Seoul (KR); Whangje Woo, Seoul (KR)

(21) Appl. No.: 15/834,628

(22) Filed: Dec. 7, 2017

(30) Foreign Application Priority Data
Jun. 29, 2017 (KR) 10-2017-0082395

(51) Int. Cl. H01L 27/32; H01L 21/02; H01L 29/51; H01L 51/52; H01L 51/56; H01L 29/49

(52) U.S. Cl. CPC H01L 27/3262; H01L 27/1222; H01L 21/02205; H01L 21/02178; H01L 29/517; H01L 21/02568; H01L 21/02527; H01L 51/5253; H01L 51/56; H01L 29/4908; H01L 21/02189; H01L 21/02181; H01L 2227/323; H01L 2251/5338; H01L 21/0228

(57) ABSTRACT

A method of manufacturing a semiconductor element is provided as follows. A semiconductor layer that has a two-dimensional layered structure is formed on a substrate having a source region, a drain region, and a channel region. A high-k insulating layer is formed on the semiconductor layer by atomic layer deposition using trimethyl aluminum as a precursor and isopropyl alcohol as a reactant gas. A gate electrode is formed in the channel region on the high-k insulating layer. An insulating interlayer is formed on the gate electrode. Source and drain electrodes are formed in the source and drain regions on the insulating interlayer.

### CROSS-REFERENCE TO RELATED APPLICATION

This application claims priority to and the benefit of Korean Patent Application No. 10-2017-0082395, filed on Jun. 29, 2017 in the Korean Intellectual Property Office (KIPO), the entire contents of which are incorporated herein by reference.

### BACKGROUND

### 1. Field

Example embodiments relate generally to methods of manufacturing a semiconductor element, organic light emitting display device including a semiconductor element, and methods of manufacturing an organic light emitting display device. For example, embodiments of the present disclosure relate to methods of manufacturing a semiconductor element including a semiconductor layer having a two-dimensional layered structure, organic light emitting display device including a semiconductor element, and methods of manufacturing an organic light emitting display device.

### 2. Description of the Related Art

A flat panel display (FPD) device is widely used as a display device of an electronic device because the FPD device is lightweight and thin compared to a cathode-ray tube (CRT) display device. Non-limiting examples of the FPD device include a liquid crystal display (LCD) device and an organic light emitting display (OLED) device.

Recently, a flexible OLED device capable of bending or folding a portion of the OLED device by including lower and upper substrates of a display panel, which are included in the OLED device, having flexible materials has been developed. Here, when the flexible OLED device is bent, a silicon semiconductor element and an oxide semiconductor element, which are included in the flexible OLED device, that are located at a bent portion may be damaged during bending or folding. In addition, a silicon-based semiconductor element and a metal oxide-based semiconductor element may have problems such as a low mobility (e.g., a low carrier mobility), a high resistance, a difficulty in controlling a threshold voltage according to the thickness, a difficulty in adjusting cation composition ratio, defects due to oxygen, etc.

### SUMMARY

Some example embodiments provide a method of manufacturing a semiconductor element including a semiconductor layer having a two-dimensional layered structure.

Some example embodiments provide an organic light emitting display device including a semiconductor element and a method of manufacturing an organic light emitting display device.

According to some example embodiments, a method of manufacturing a semiconductor element is provided as follows. A semiconductor layer that has a two-dimensional layered structure is formed on a substrate having a source region, a drain region, and a channel region. A high dielectric constant (high-k) insulating layer is formed on the semiconductor layer by atomic layer deposition (ALD) using tri-Methyl-aluminum (TMA) as a precursor and isopropyl alcohol (IPA) as a reactant gas. A gate electrode is formed in the channel region on the high-k insulating layer. An insulating interlayer is formed on the gate electrode. Source and drain electrodes are formed in the source and drain regions on the insulating interlayer.

In example embodiments, the forming of the high-k insulating layer on the semiconductor layer by the ALD method using the TMA as the precursor and the IPA as the reactant gas may include adsorbing aluminum atoms on the substrate by injecting a TMA gas, injecting a first purge gas after the TMA gas is injected, reacting the IPA and the aluminum atom that is adsorbed on the substrate by injecting an IPA gas after the first purge gas is injected, and injecting a second purge gas after the IPA gas is injected.

In example embodiments, the high-k insulating layer may consist essentially of alumina (Al₂O₃).

In example embodiments, the high-k insulating layer may include one selected from the group consisting of alumina (Al₂O₃), zirconium oxide (ZrO2), and hafnium oxide (HfO2).

In example embodiments, the semiconductor layer having the two-dimensional layered structure may include transition metal dichalcogenide (TMDC) and graphene.

In example embodiments, the semiconductor layer having the two-dimensional layered structure may include one selected from the group consisting of molybdenum disulfide (MoS2), molybdenum diselenide (MoSe2), molybdenum ditelluride (MoTe2), tungsten disulfide (WS2), tungsten diselenide (WSe2), tungsten ditelluride (WTe2), zirconium disulfide (ZrS2), zirconium diselenide (ZrSe2), and hexagonal boron nitride (hBN) graphene.

In example embodiments, the semiconductor layer having the two-dimensional layered structure may consist essentially of molybdenum disulfide (MoS2).

In example embodiments, the semiconductor layer may not include a molybdenum-oxygen (Mo—O) bond and a disulfide-oxygen (S—O) bond.

According to some example embodiments, a method of manufacturing an organic light emitting display (OLED) device is provided as follows. A substrate having a source region, a drain region, and a channel region is provided. A semiconductor element including a semiconductor layer, a high-k insulating layer, a gate electrode, an insulating interlayer, and source and drain electrodes is formed. The semiconductor layer that has a two-dimensional layered structure is formed in the source region, the drain region, and the channel region on the substrate. The high-k insulating layer is formed on the semiconductor layer by ALD using TMA as a precursor and IPA as a reactant gas. The gate electrode is formed in the channel region on the high-k insulating layer. The insulating interlayer is formed on the gate electrode. The source and drain electrodes are formed in the source and drain regions on the insulating interlayer. A pixel structure is formed on the semiconductor layer. A thin film encapsulation (TFE) structure is formed on the pixel structure.

In example embodiments, the forming of the pixel structure on the semiconductor layer may include forming a lower electrode such that the lower electrode is electrically coupled to (e.g., electrically connected to) the drain electrode, forming a light emitting layer on the lower electrode, and forming an upper electrode on the light emitting layer.

In example embodiments, the forming of the thin film encapsulation structure on the pixel structure may include forming a first TFE layer having inorganic materials on the upper electrode, forming a second TFE layer having organic materials on the first TFE layer, and forming a third TFE layer having inorganic materials on the second TFE layer.

In example embodiments, the substrate and the TFE structure may include flexible materials.

In example embodiments, the forming of the high-k insulating layer on the semiconductor layer by the ALD method using the TMA as the precursor and the IPA as the reactant gas may include adsorbing aluminum atoms on the substrate by injecting a TMA gas, injecting a first purge gas after the TMA gas is injected, reacting the IPA and the aluminum atom that is adsorbed on the substrate by injecting an IPA gas after the first purge gas is injected, and injecting a second purge gas after the IPA gas is injected.

In example embodiments, the high-k insulating layer may consist essentially of alumina (Al₂O₃).

In example embodiments, the semiconductor layer having the two-dimensional layered structure may consist essentially of MoS2.

In example embodiments, the semiconductor layer may not include a Mo—O bond and an S—O bond.

According to some example embodiments, an OLED device includes a substrate, a semiconductor layer, a high-k insulating layer, a gate electrode, an insulating interlayer, source and drain electrodes, a pixel structure, and a TFE structure. The substrate has a source region, a drain region, and a channel region. The semiconductor layer is disposed in the source region, the drain region, and the channel region on the substrate, and consists essentially of MoS2. The high-k insulating layer covers the semiconductor layer on the substrate, and consists essentially of Al₂O₃. The gate electrode is disposed in the channel region on the high-k insulating layer. The insulating interlayer covers the gate electrode on the high-k insulating layer. The source and drain electrodes are disposed in the source and drain regions on the insulating interlayer. The pixel structure is disposed on the source and drain electrodes. The TFE structure is disposed on the pixel structure.

In example embodiments, the semiconductor layer may not include a Mo—O bond and an S—O bond.

In example embodiments, the substrate and the TFE structure may include flexible materials.

In a method of manufacturing the semiconductor element according to example embodiments, the semiconductor layer may not be oxidized in a process for forming the high-k insulating layer, and may not be damaged by an oxygen bond. In addition, since the electron doping phenomenon is generated in MoS₂ of the semiconductor layer, the element characteristic of a semiconductor element may be increased. Accordingly, the semiconductor element having a relatively high element characteristic may be manufactured.

In the ALD process for forming the high-k insulating layer in accordance with example embodiments, as the IPA is used as the reactant gas, the semiconductor layer included in the OLED device may not be damaged by oxygen bond. In addition, since the electron doping phenomenon occur in the semiconductor layer, the element characteristic of the semiconductor element may be increased. Further, since the OLED device includes the semiconductor layer that is readily bent and has a rigid characteristic, the OLED device may serve as a flexible OLED device including the semiconductor element having relatively high characteristics.

In a method of manufacturing the OLED device according to example embodiments, as the IPA as a reactant gas is used in the ALD process for forming the high-k insulating layer 150, the semiconductor layer included in the OLED device may not be damaged by an oxygen bond. In addition, since the electron doping phenomenon is generated in the semiconductor layer, the element characteristic of a semiconductor element may be increased. Further, since the OLED device includes the semiconductor layer that is readily bent and has a rigid characteristic, the OLED device may serve as a flexible OLED device including the semiconductor element having relatively high characteristics.

### BRIEF DESCRIPTION OF THE DRAWINGS

Example embodiments can be understood in more detail from the following description taken in conjunction with the accompanying drawings, in which:

FIG. 1 is a cross sectional view illustrating a semiconductor element in accordance with example embodiments;

FIGS. 2-8 are cross-sectional views illustrating methods of manufacturing a semiconductor element in accordance with example embodiments;

FIGS. 9A-9B are graphs illustrating a bond between an oxygen atom and an atom that constitutes a semiconductor layer of FIG. 7 and a bond between an oxygen atom and an atom of a semiconductor layer of comparative examples;

FIGS. 10A-10C are graphs illustrating a photoluminescence intensity with respect to trion and exciton of a semiconductor layer of FIG. 7 and comparative examples;

FIG. 10D is a graph illustrating an element characteristic of semiconductor elements of FIGS. 10B-10C;

FIG. 11 is a cross-sectional view illustrating an organic light emitting display (OLED) device in accordance with example embodiments; and

FIGS. 12-20 are cross-sectional views illustrating a method of manufacturing an OLED device in accordance with example embodiments.

### DETAILED DESCRIPTION

Hereinafter, embodiments of the present disclosure will be explained in more detail with reference to the accompanying drawings.

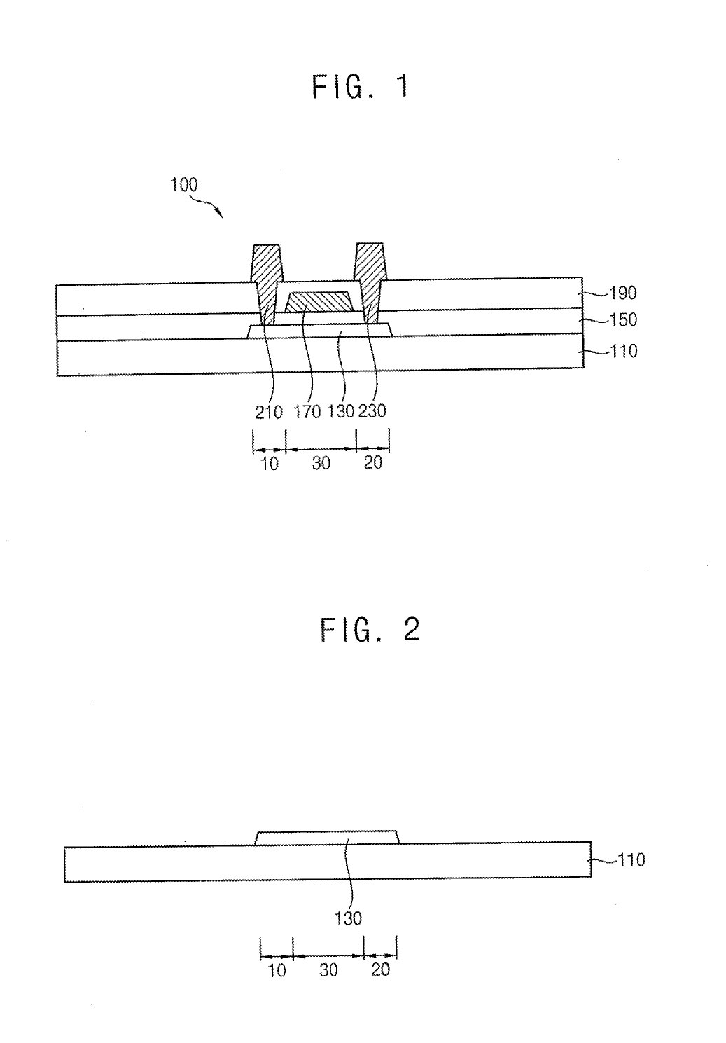

FIG. 1 is a cross sectional view illustrating a semiconductor element in accordance with example embodiments.

Referring to FIG. 1, a semiconductor element 100 may include a substrate 110, a semiconductor layer 130, a high dielectric constant (high-k) insulating layer 150, a gate electrode 170, an insulating interlayer 190, a source electrode 210, and a drain electrode 230.

The substrate 110 may include transparent materials and/or opaque materials. The substrate 110 may have a source region 10, a drain region 20, and a channel region 30. The substrate 110 may include a flexible transparent material such as a flexible transparent resin substrate. The substrate 110 may have a structure in which a first organic layer, a first barrier film layer, a second organic layer, a second barrier film layer are sequentially stacked. The first and second barrier film layers may include inorganic materials, and the first and second organic layers may include organic materials. In some embodiments, the substrate 110 may include a quartz substrate, a synthetic quartz substrate, a calcium fluoride substrate, a fluoride-doped quartz substrate, a sodalime glass substrate, a non-alkali glass substrate, etc.

A buffer layer may be disposed on the substrate 110. In some embodiments, the buffer layer may be disposed on the entire substrate 110. The buffer layer may prevent the diffusion of metal atoms and/or impurities from the substrate 110 into the semiconductor element 100 (or may reduce a likelihood or degree of such diffusion). In addition, the buffer layer may improve a surface flatness (e.g., surface smoothness) of the substrate 110 when a surface of the substrate 110 is relatively irregular (e.g., rough). According to a type (e.g., composition) of the substrate 110, at least two buffer layers may be provided on the substrate 110, or the buffer layer may not be disposed (e.g., the buffer layer may be omitted). For example, the buffer layer may include a silicon compound, a metal oxide, etc.

The semiconductor layer 130 may be disposed in the source region 10, the drain region 20, and the channel region 30 on the substrate 110. In example embodiments, the semiconductor layer 130 may include a semiconductor layer having a two-dimensional layered structure (2DLS).

For example, compared to a silicon-based semiconductor layer or a metal oxide-based semiconductor layer, the semiconductor layer having the 2DLS may have a thin thickness, a high mobility (e.g., a high carrier mobility), a high on/off current ratio, and a high stability. In addition, the semiconductor layer having the 2DLS may have a nanoplate structure, but may be used as a semiconductor layer because a band gap exists (e.g., the 2DLS semiconductor layer has a band gap). Further, since the semiconductor layer having the 2DLS is readily bent and has a rigid characteristic, the semiconductor layer having the 2DLS may be used as a semiconductor layer of a semiconductor element included in a flexible display device. However, the semiconductor layer having the 2DLS includes small atoms (e.g., atoms having a size of several nanometers), and since the small atoms are arranged in one layer (or at least one layer), the semiconductor layer having the 2DLS may be very sensitive to defects due to oxygen in a process for forming a high-k insulating layer on the semiconductor layer having the 2DLS. Here, when the high-k insulating layer is formed on the semiconductor layer having the 2DLS, the semiconductor layer having the 2DLS may be bonded to oxygen in a process for forming the high-k insulating layer because the high-k insulating layer is formed by an atomic layer deposition (ALD) method generally using ozone, oxygen, water, etc. as a reactant gas (or oxidizing agent). In other words, when the atoms constituting the semiconductor layer having the 2DLS are bonded to oxygen, the semiconductor layer having the 2DLS may be oxidized and may be significantly damaged by the high-k insulating layer.

The semiconductor layer having the 2DLS may include a transition metal dichalcogenide (TMDC), graphene, etc. Here, the TMDC may include molybdenum disulfide (MoS₂), molybdenum diselenide (MoSe₂), molybdenum ditelluride (MoTe₂), tungsten disulfide (WS₂), tungsten diselenide (WSe₂), tungsten ditelluride (WTe₂), zirconium disulfide (ZrS₂), zirconium diselenide (ZrSe₂), etc., and the graphene may include hexagonal boron nitride (hBN) graphene, boron nitride co-doped graphene (BCN) graphene, etc. For example, the semiconductor layer 130 may consist essentially of MoS₂. In example embodiments, the semiconductor layer 130 may not include a molybdenum-oxygen (Mo—O) bond and/or a disulfide-oxygen (S—O) bond (e.g., the semiconductor layer 130 may be substantially free or completely free of compounds that have a molybdenum-oxygen (Mo—O) bond and/or a disulfide-oxygen (S—O) bond).

The high-k insulating layer 150 may be disposed on the semiconductor layer 130. The high-k insulating layer 150 may cover the semiconductor layer 130 on the substrate 110, and may be disposed on the entire substrate 110. For example, the high-k insulating layer 150 may suitably or sufficiently cover the semiconductor layer 130 on the substrate 110, and may have a substantially level surface without a step (e.g., a step defect) around the semiconductor layer 130. In some embodiments, the high-k insulating layer 150 may cover the semiconductor layer 130 on the substrate 110, and may be disposed to a substantially uniform thickness along a profile of the semiconductor layer 130. In example embodiments, the high-k insulating layer 150 may be formed by the ALD method, and tri-Methyl-aluminum (TMA) as a precursor and isopropyl alcohol (IPA) as a reactant gas may be used in the ALD method. In other words, the IPA may be used as a reactant gas in the ALD method according to example embodiments, and thus, ozone, oxygen, water, etc. may not be used as a reactant gas. For example, the IPA having a relatively low oxidizing power and a relatively large molecular size may be used as an oxidizing agent without using the oxidizing agent having a high oxidizing power such as ozone, oxygen, water, etc. Thus, in some embodiments, the ALD may be performed utilizing a reactant gas substantially free of ozone, oxygen, water, and the like, and in some embodiments the reactant gas consists essentially of, or consists of, IPA. As used herein, the statement “reactant gas substantially free of ozone, oxygen, water, and the like” means that oxidants such ozone, oxygen, water, and other compounds having similar oxidizing strength are present in the reactant gas, if at all, as only incidental impurities. Accordingly, the semiconductor layer 130 may not be damaged (e.g., may not be substantially damaged) by an oxygen bond in a process for forming the high-k insulating layer 150. In addition, when the high-k insulating layer 150 is formed on the semiconductor layer 130 by the ALD method using the IPA, an electron doping phenomenon may be generated in the semiconductor layer 130. Accordingly, an element characteristic of the semiconductor element 100 may be increased by about 100 to 1000 times. The high-k insulating layer 150 may include materials where dielectric constant K is more than 8. For example, the high-k insulating layer 150 may include an insulation layer having a high dielectric constant such as alumina (Al₂O₃), zirconium oxide (ZrO₂), and hafnium oxide (HfO₂), etc. In example embodiments, the high-k insulating layer 150 may consist essentially of Al₂O₃.

The gate electrode 170 may be disposed in the channel region 30 on the high-k insulating layer 150. The gate electrode 170 may include a metal, a metal alloy, metal nitride, conductive metal oxide, transparent conductive materials, etc. For example, the gate electrode 170 may include gold (Au), silver (Ag), aluminum (Al), platinum (Pt), nickel (Ni), titanium (Ti), palladium (Pd), magnesium (Mg), Calcium (Ca), Lithium (Li), chrome (Cr), tantalum (Ta), tungsten (W), copper (Cu), molybdenum (Mo), scandium (Sc), neodymium (Nd), Iridium (Ir), an alloy of aluminum, aluminum nitride (AINx), an alloy of silver, tungsten nitride (WNx), an alloy of copper, an alloy of molybdenum, titanium nitride (TiNx), chrome nitride (CrNx), tantalum nitride (TaNx), strontium ruthenium oxide (SRO), zinc oxide (ZnOx), indium tin oxide (ITO), stannum oxide (SnOx), indium oxide (InOx), gallium oxide (GaOx), indium zinc oxide (IZO), etc. These may be used alone or in a suitable combination thereof. In some example embodiments, the gate electrode 170 may have a multi-layered structure.

The insulating interlayer 190 may be disposed on the gate electrode 170. The insulating interlayer 190 may cover the gate electrode 170 on the high-k insulating layer 150, and may be disposed on the entire high-k insulating layer 150. The insulating interlayer 190 may include a silicon compound, a metal oxide, etc. For example, the insulating interlayer 190 may include silicon oxide (SiOx), silicon nitride (SiNx), silicon oxynitride (SiOxNy), silicon oxycarbide (SiOxCy), silicon carbon nitride (SiCxNy), aluminum oxide (AlOx), aluminum nitride (AINx), tantalum oxide (TaOx), hafnium oxide (HfOx), zirconium oxide (ZrOx), titanium oxide (TiOx), etc.

The source electrode 210 and the drain electrode 230 may be disposed on the insulating interlayer 190. The source electrode 210 may be in direct contact (e.g., physical contact) with the source region 10 of the semiconductor layer 130 via a contact hole formed by removing a portion of the high-k insulating layer 150 and the insulating interlayer 190. The drain electrode 230 may be in direct contact (e.g., physical contact) with the drain region 20 of the semiconductor layer 130 via a contact hole formed by removing another portion of the high-k insulating layer 150 and the insulating interlayer 190. Each of the source electrode 210 and the drain electrode 230 may include a metal, an alloy, a metal nitride, a conductive metal oxide, transparent conductive materials, etc. These may be used alone or in a suitable combination thereof. In some example embodiments, each of the source and drain electrodes 210 and 230 may have a multi-layered structure. Accordingly, the semiconductor element 100 including the semiconductor layer 130, the high-k insulating layer 150, the gate electrode 170, the insulating interlayer 190, the source electrode 210, and the drain electrode 230 may be disposed.

In example embodiments, the semiconductor element 100 has a top gate structure, but the present disclosure is limited thereto. For example, in some example embodiments, the semiconductor element 100 may have a bottom gate structure or a double gate structure.

In the ALD process for forming the high-k insulating layer 150 in accordance with example embodiments, as the IPA is used as the reactant gas, the semiconductor layer 130 may not be damaged (e.g., may not be substantially damaged) by oxygen bond (e.g., the semiconductor layer 130 may not react with the reactant gas to form an oxygen bond to an atom of the semiconductor layer 130). Accordingly, the semiconductor element 100 may serve as a semiconductor element of the 2DLS having a relatively thin thickness, a relatively high mobility (e.g., a relatively high carrier mobility), a relatively high on/off current ratio, a relatively high stability. In addition, since the electron doping phenomenon occurs in the semiconductor layer 130, the element characteristic of the semiconductor element 100 may be increased.

FIGS. 2, 3, 4, 5, 6, 7, and 8 are cross-sectional views illustrating a method of manufacturing a semiconductor element in accordance with example embodiments.

Referring to FIG. 2, a substrate 110 including transparent materials or opaque materials may be provided. The substrate 110 may have a source region 10, a drain region 20, and a channel region 30. The substrate 110 may be formed using a flexible transparent material such as a flexible transparent resin substrate. In some embodiments, the substrate 110 may be formed using a quartz substrate, a synthetic quartz substrate, a calcium fluoride substrate, a fluoride-doped quartz substrate, a sodalime glass substrate, a non-alkali glass substrate, etc.

A buffer layer may be formed on the substrate 110. The buffer layer may be formed on the entire substrate 110. The buffer layer may prevent the diffusion of metal atoms and/or impurities from the substrate 110 into a semiconductor element (or may reduce a likelihood or degree of such diffusion). In addition, the buffer layer may improve a surface flatness (e.g., surface smoothness) of the substrate 110 when a surface of the substrate 110 is relatively irregular (e.g., rough). According to a type (e.g., composition) of the substrate 110, at least two buffer layers may be provided on the substrate 110, or the buffer layer may not be disposed (e.g., the buffer layer may be omitted). For example, the buffer layer may be formed using silicon compound, metal oxide, etc.

A semiconductor layer 130 may be formed in the source region 10, the drain region 20, and the channel region 30 on the substrate 110. In example embodiments, the semiconductor layer 130 may be formed using a semiconductor layer having a 2DLS. The semiconductor layer having the 2DLS may consist essentially of TMDC, graphene, etc. In example embodiments, the semiconductor layer 130 may include one selected from the group consisting of MoS₂, MoSe₂, MoTe₂, WS₂, WSe₂, WTe₂, ZrS₂, ZrSe₂, hBN graphene, BCN graphene, etc. For example, the semiconductor layer 130 may consist essentially of MoS₂. In example embodiments, the semiconductor layer 130 may not include a molybdenum-oxygen (Mo—O) bond and/or a disulfide-oxygen (S—O) bond. For example, the semiconductor layer 130 may consist essentially of MoS₂.

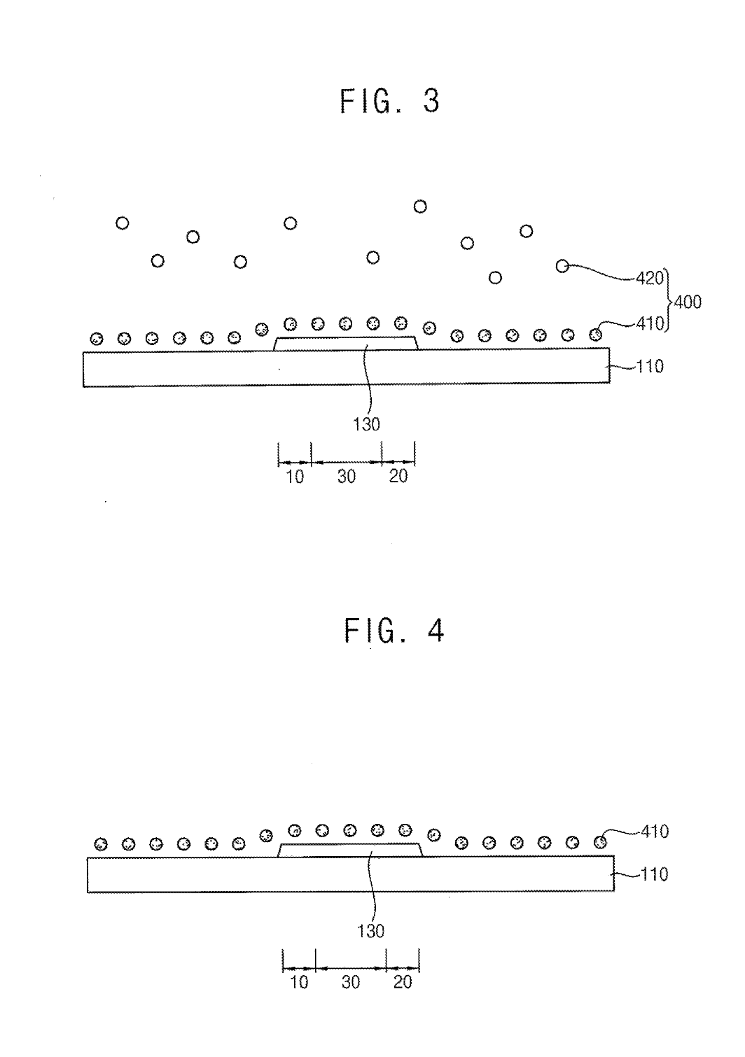

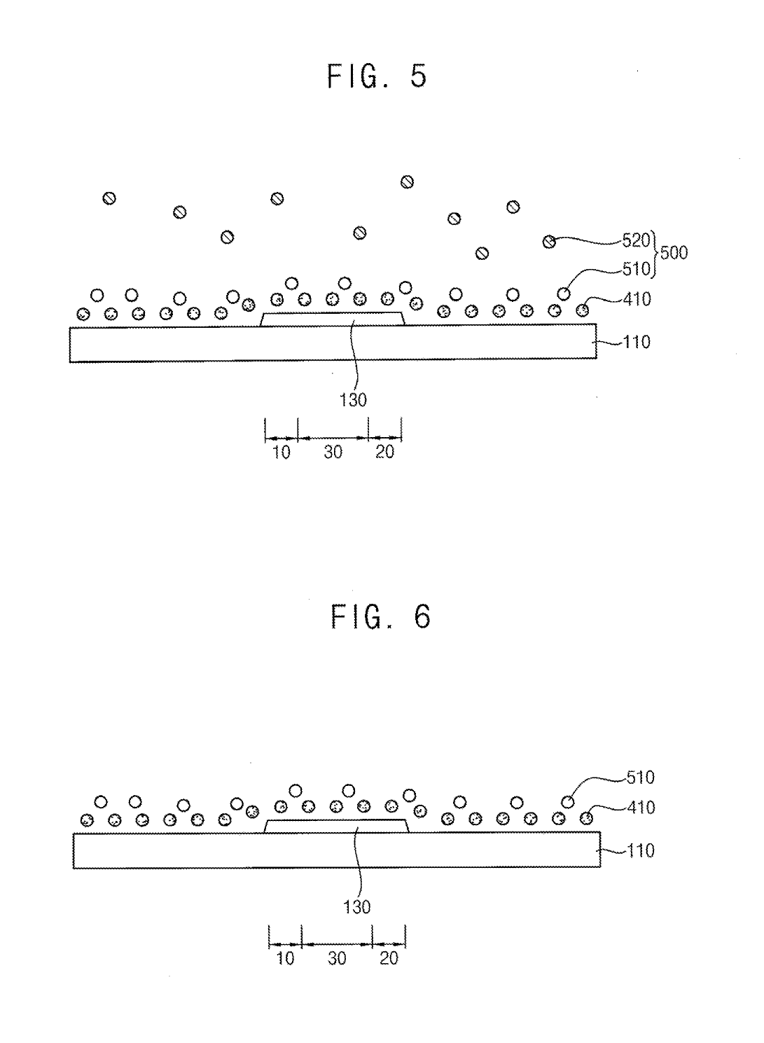

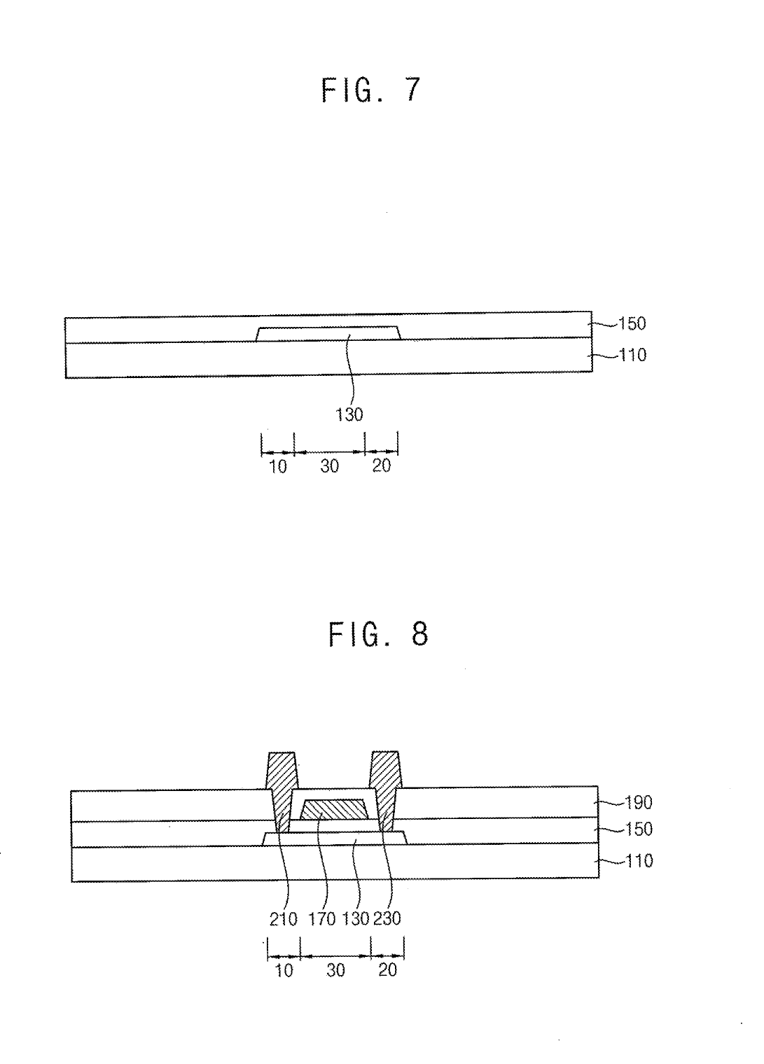

Referring to FIGS. 3, 4, 5, 6, and 7, a high-k insulating layer 150 may be formed by an ALD method. In example embodiments, TMA as a precursor and an IPA as a reactant gas may be used in the ALD method. For example, FIG. 3 is a cross-sectional view illustrating an active act of injecting a precursor, and FIG. 4 is a cross-sectional view illustrating an active act of injecting a first purge gas. In addition, FIG. 5 is a cross-sectional view illustrating an active act of injecting a reactant gas, and FIG. 6 is a cross-sectional view illustrating an active act of injecting a second purge gas. Further, FIG. 7 is a cross-sectional view illustrating the high-k insulating layer 150 that is formed on the substrate 110.

Referring again to FIG. 3, a TMA gas 400 may be injected in a chamber such that atoms included in the TMA gas 400 are adsorbed on the substrate 110 and the semiconductor layer 130. For example, a plasma treatment process may be performed by using the TMA gas 400. In this embodiment, the atoms included in the TMA gas 400 may be adsorbed to each other (e.g., adsorbed onto each other), or may be adsorbed on the substrate 110 and the semiconductor layer 130. For example, as the adsorption between the atoms is a physisorption, a bonding force between the atoms may be weak. On the other hand, as the adsorption where atoms are adsorbed on the substrate 110 and the semiconductor layer 130 is a chemisorption, a bonding force between the atoms may be strong.

The TMA gas 400 may include a first TMA compound (or atom thereof) 410 and a second TMA compound (or atom thereof) 420. The first TMA compounds (or atoms thereof) 410 may be adsorbed on the substrate 110 and the semiconductor layer 130 in the chamber, and the second TMA compounds (or atoms thereof) 420 may be adsorbed to each other in the chamber or may be present alone in the chamber.

Referring again to FIG. 4, a first purge gas may be injected after the TMA gas 400 is injected. When the first purge gas is injected, the second TMA compounds (or atoms thereof) 420 may be removed from the chamber, and the first TMA compounds (or atoms thereof) 410 may remain on the substrate 110 and the semiconductor layer 130. The first purge gas may include argon (Ar), nitrogen (N₂), etc.

Referring again to FIG. 5, an IPA gas 500 may be injected in the chamber such that IPA compounds (or atoms thereof) included in the IPA gas 500 and the first TMA compound (or atom thereof) 410 that is adsorbed on the substrate 110 and the semiconductor layer 130 are reacted after the first purge gas is injected. For example, a plasma treatment process may be performed by using the IPA gas 500. The IPA gas 500 may include a first IPA compound (or atom thereof) 510 and a second IPA compound (or atom thereof) 520. The first IPA compounds (or atoms thereof) 510 may be combined with (or bonded to) the first TMA compounds (or atoms thereof) 410. In this case, Al₂O₃ may be formed. The second IPA compounds (or atoms thereof) 520 may be adsorbed to each other in the chamber or may be present alone in the chamber.

For example, in a general ALD method, ozone, oxygen, water, etc. may be used as a reactant gas, and a semiconductor layer having the 2DLS may be bonded to oxygen in a process for injecting the reactant gas. In this case, when atoms of the semiconductor layer having the 2DLS are bonded to oxygen, the semiconductor layer having the 2DLS may be oxidized and may be significantly damaged by the high-k insulating layer. A method of manufacturing a semiconductor element according to example embodiments, the IPA gas 500 may be used as the reactant gas such that the IPA compounds (or atoms thereof) that are included in the IPA gas 500 are reacted with the first TMA compounds (or atoms thereof) 410 that are adsorbed on the substrate 110 and the semiconductor layer 130. Accordingly, the semiconductor layer 130 according to embodiments of the present disclosure may not be damaged by oxygen bond. In addition, when the Al₂O₃ is formed on the semiconductor layer 130 by the ALD method using the IPA gas 500 as the reactant gas, an electron doping phenomenon may be generated in MoS₂ of the semiconductor layer 130. Accordingly, the element characteristic of a semiconductor element may be increased.

Referring again to FIG. 6, a second purge gas may be injected after the IPA gas 500 is injected. When the second purge gas is injected, the second IPA compounds (or atoms thereof) 520 may be removed from the chamber, and the first IPA compounds (or atoms thereof) 510 combined with the first TMA compound (or atom thereof) 410 may remain. The second purge gas may include Ar, N₂, etc. Accordingly, one alumina layer having a high dielectric constant may be formed, and a high-k insulating layer 150 illustrated in FIG. 7 may be formed on the substrate 110 and the semiconductor layer 130 by repeating processes illustrated in FIGS. 3, 4, 5, and 6. In example embodiments, the high-k insulating layer 150 may include materials where dielectric constant K is more than 8.

Referring to FIG. 8, a gate electrode 170 may be formed in the channel region 30 on the high-k insulating layer 150. The gate electrode 170 may be formed using a metal, a metal alloy, a metal nitride, a conductive metal oxide, transparent conductive materials, etc. For example, the gate electrode 170 may include Au, Ag, Al, Pt, Ni, Ti, Pd, Mg, Ca, Li, Cr, Ta, W, Cu, Mo, Sc, Nd, Ir, an alloy of aluminum, AINx, an alloy of silver, WNx, an alloy of copper, an alloy of molybdenum, TiNx, CrNx, TaNx, SRO, ZnOx, ITO, SnOx, InOx, GaOx, IZO, etc. These may be used alone or in a suitable combination thereof. In some example embodiments, the gate electrode 170 may have a multi-layered structure.

An insulating interlayer 190 may be formed on the gate electrode 170. In some embodiments, the insulating interlayer 190 may cover the gate electrode 170 on the high-k insulating layer 150, and may be formed on the entire high-k insulating layer 150. The insulating interlayer 190 may be formed using a silicon compound, a metal oxide, etc. For example, the insulating interlayer 190 may include SiOx, SiNx, SiOxNy, SiOxCy, SiCxNy, AlOx, AINx, TaOx, HfOx, ZrOx, TiOx, etc.

A source electrode 210 and a drain electrode 230 may be formed on the insulating interlayer 190. The source electrode 210 may be in direct contact (e.g., physical contact) with the source region 10 of the semiconductor layer 130 via a contact hole formed by removing a portion of the high-k insulating layer 150 and the insulating interlayer 190. The drain electrode 230 may be in direct contact (e.g., physical contact) with the drain region 20 of the semiconductor layer 130 via a contact hole formed by removing another portion of the high-k insulating layer 150 and the insulating interlayer 190. Each of the source electrode 210 and the drain electrode 230 may be formed using a metal, an alloy, a metal nitride, a conductive metal oxide, transparent conductive materials, etc. These may be used alone or in a suitable combination thereof. In some example embodiments, each of the source and drain electrodes 210 and 230 may have a multi-layered structure. Accordingly, a semiconductor element 100 including the semiconductor layer 130, the high-k insulating layer 150, the gate electrode 170, the insulating interlayer 190, the source electrode 210, and the drain electrode 230 illustrated in FIG. 1 may be formed.

In a method of manufacturing a semiconductor element according to example embodiments, the semiconductor layer 130 may not be oxidized in a process for forming the high-k insulating layer 150, and may not be damaged by an oxygen bond. In addition, since the electron doping phenomenon is generated in MoS₂ of the semiconductor layer 130, the element characteristic of a semiconductor element may be increased. Accordingly, the semiconductor element 100 having a relatively high element characteristic may be manufactured.

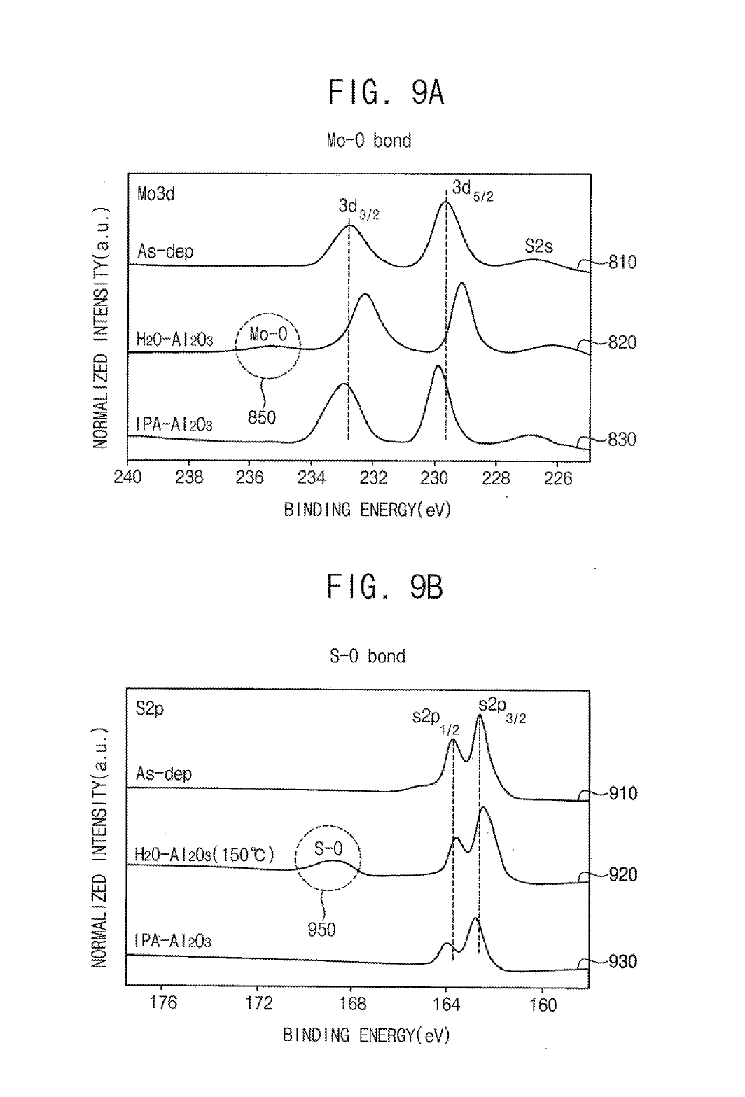

FIGS. 9A-9B are graphs illustrating a bond between an oxygen atom and atom that constitutes a semiconductor layer of FIG. 7 and a bond between oxygen atom and atom of comparative examples. For example, FIG. 9A is a graph illustrating a molybdenum and oxygen (Mo—O) bond, and FIG. 9B is a graph illustrating a disulfide and oxygen (S—O) bond.

The following Examples and Comparative Examples are provided in order to illustrate characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Experimental Example: Measurement of Mo—O Bond Varying Reactant Gas

The Mo—O bond is measured after the Mo is formed on a substrate (refer to a first graph (e.g., trace) 810 of FIG. 9A, which shows the results for the as-deposited molybdenum without further processing).

In addition, the Mo—O bond is measured after alumina is formed on the Mo by an ALD method using water as a reactant gas (refer to a second graph 820 of FIG. 9A).

Meanwhile, the Mo—O bond is measured after alumina is formed on the Mo by the ALD method using an IPA as a reactant gas (refer to a third graph 830 of FIG. 9A).

As illustrated in FIG. 9A, Comparative Example 1 may correspond to the first graph 810 of FIG. 9A, and Comparative Example 2 may correspond to the second graph 820 of FIG. 9A. In addition, Example may be correspond to the third graph 830 of FIG. 9A.

The Mo—O bond is generated in a first portion 850 of the second graph 820 of FIG. 9A, and the Mo—O bond is not generated in the third graph 830 of FIG. 9A because the first graph 810 is substantially the same as the third graph 830.

### Experimental Example: Measurement of S—O Bond Varying Reactant Gas

The S—O bond is measured after the S is formed on a substrate (refer to a first graph 710 of FIG. 9B, which shows the results for the as-deposited S without further processing).

In addition, the S—O bond is measured after alumina is formed on the S by an ALD method using water as a reactant gas (refer to a second graph 920 of FIG. 9B).

Meanwhile, the S—O bond is measured after alumina is formed on the S by the ALD method using an IPA as a reactant gas (refer to a third graph 930 of FIG. 9B).

As illustrated in FIG. 9B, Comparative Example 1 may correspond to the first graph 910 of FIG. 9B, and Comparative Example 2 may correspond to the second graph 920 of FIG. 9B. In addition, Example may correspond to the third graph 930 of FIG. 9B.

The S—O bond is generated in a first portion 950 of the second graph 920 of FIG. 9B, and the S—O bond is not generated in the third graph 930 of FIG. 9B because the first graph 910 is substantially the same as the third graph 930.

The semiconductor layer 130 according to example embodiments may not be oxidized in a process for forming the high-k insulating layer 150. Accordingly, the semiconductor layer 130 may not be damaged by an oxygen bond.

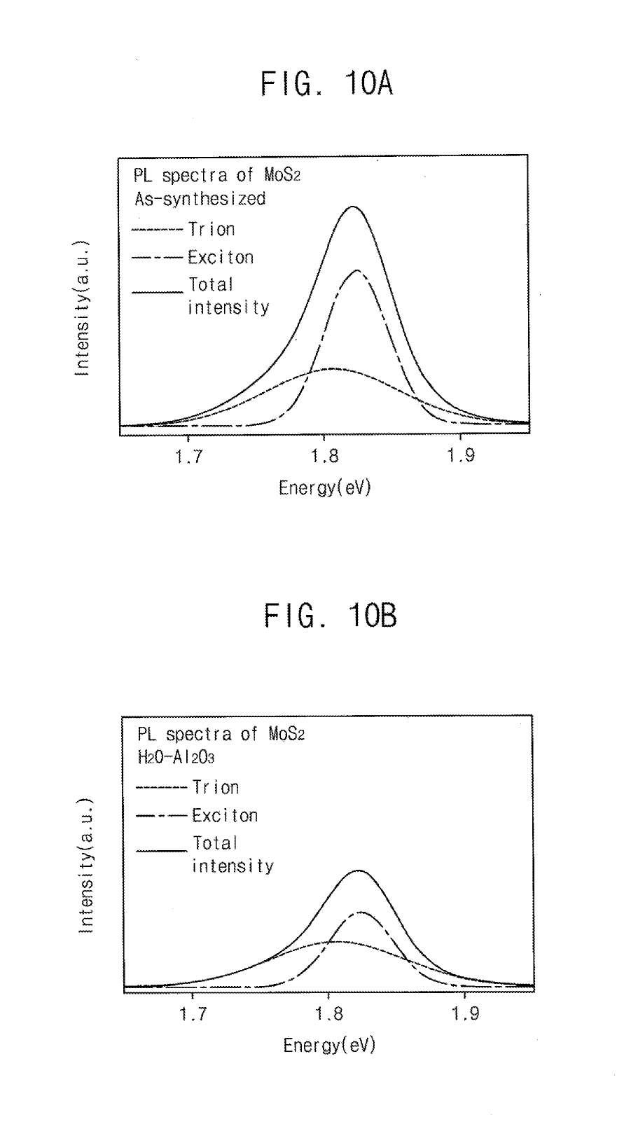

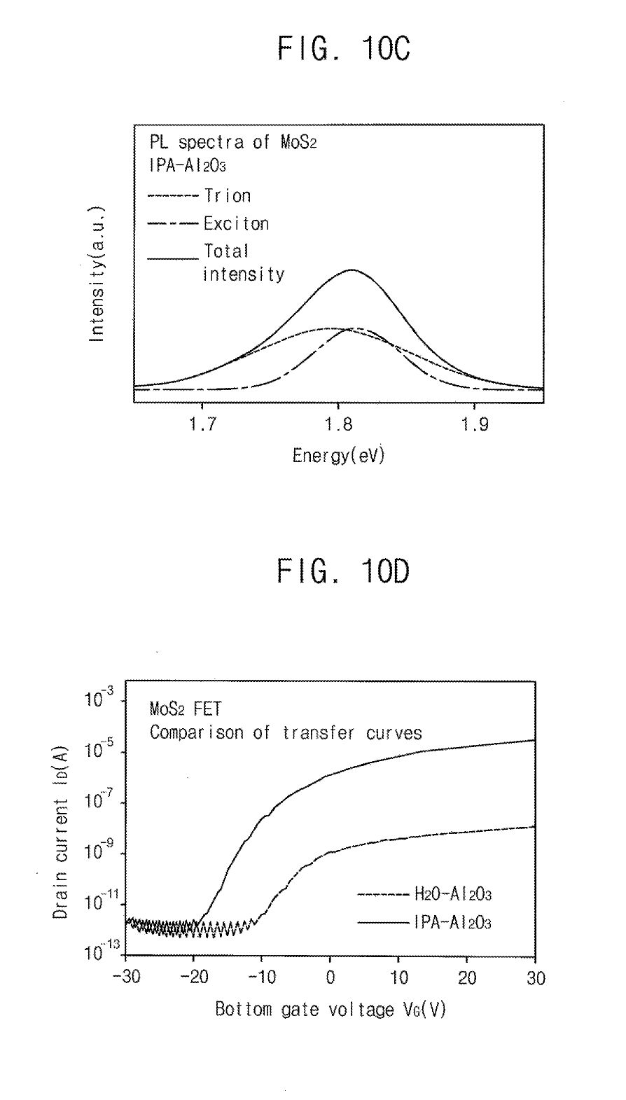

FIGS. 10A-10C are graphs illustrating a photoluminescence intensity with respect to trion and exciton of a semiconductor layer of FIG. 7 and comparative examples, and FIG. 10D is a graph illustrating an element characteristic of semiconductor elements of FIGS. 10B-10C.

### Experimental Example: Measurement of Trion and Exciton of Semiconductor Layer Varying Reactant Gas

A photoluminescence intensity with respect to the trion and the exciton of MoS₂ (e.g., the semiconductor layer) is measured after a semiconductor layer is formed on a substrate (refer to FIG. 10A).

In addition, the photoluminescence intensity with respect to the trion and the exciton of the MoS₂ is measured after alumina is formed on the semiconductor layer by an ALD method using water as a reactant gas (refer to FIG. 10B).

Meanwhile, the photoluminescence intensity with respect to the trion and the exciton of the MoS₂ is measured after alumina is formed on the semiconductor layer by the ALD method using IPA as a reactant gas (refer to FIG. 10C).

The photoluminescence intensity is measured so as to analyze luminescence characteristics of the semiconductor layer.

As illustrated in FIG. 10A, Comparative Example 1 may correspond to a graph illustrating the photoluminescence intensity with respect to the trion and the exciton of the MoS₂ (e.g., prior to an electron doping). As illustrated in FIG. 10B, Comparative Example 2 may correspond to a graph illustrating the photoluminescence intensity with respect to the trion and the exciton of the MoS₂ after alumina is formed on the MoS₂ by an ALD method using water as a reactant gas. As illustrated in FIG. 10C, the Example may correspond to a graph illustrating the photoluminescence intensity with respect to the trion and the exciton of the MoS₂ after alumina is formed on the MoS₂ by the ALD method using an IPA water as a reactant gas (e.g., after the electron doping).

An area ratio of trion or exciton to a total area of the photoluminescence intensity in Comparative Examples and Example were calculated. The calculated values are shown in Table 1 below.

TABLE 1

| | | Comparative | |
|---|---|---|---|
| | Comparative Example 1 | Example 2 | Example |
| | (FIG. 10A) | (FIG. 10B) | (FIG. 10C) |
| Trion/I_{tot.} | 0.38 | 0.4 | 0.56 |
| Exciton/I_{tot.} | 0.66 | 0.65 | 0.57 |

For example, MoS₂ may include electrons and holes that are optically generated, and the electron and the hole may be combined to each other (e.g., combined together) by a coulomb interaction between the electron and the hole. As the electron and the hole are combined, an electron-hole pair (EHP) (e.g., exciton) may be created. In addition, the exciton may be additionally combined with another electron or another hole. When the exciton is combined with another electron or another hole, a charged exciton (e.g., trion) may be created. In a ratio of the exciton and the trion, an element characteristic of a semiconductor element may be improved when a ratio of the trion is relatively high.

Compared to FIGS. 10A-10C, a peak of a trion graph in the Example became higher than a peak of a trion graph in Comparative Example 1. In addition, as illustrated in Table 1, the area ratio of the trion in the Example became larger than the area ratio of the trion in Comparative Example 1. On the other hand, a peak of an exciton graph in the Example became lower than a peak of an exciton graph in Comparative Example 1. In addition, as illustrated in Table 1, the area ratio of the exciton in the Example became smaller than the area ratio of the exciton in Comparative Example 1. In this regard, when an alumina is formed on the semiconductor layer by an ALD method using an IPA as a reactant gas, an electron doping phenomenon may occur in the MoS₂. For example, the electron doping phenomenon may be generated due to an electronegativity difference between the MoS₂ and the IPA. For example, the MoS₂ having a relatively high electronegativity may attract electrons included in the IPA having a relatively low electronegativity, and the electrons may be combined with the exciton in the MoS₂. When the electrons are combined with the exciton in the MoS₂, the electrons may be converted into a trion. Accordingly, when the alumina is formed on the semiconductor layer by using the IPA, the trion may be increased in the MoS₂, as illustrated in Table 1. In addition, an element characteristic of the semiconductor element may be increased by about 100 to 1000 times, as illustrated in FIG. 10D.

Compared to FIGS. 10A-10B, a peak of a trion graph in Comparative Example 2 became slightly lower than the peak of the trion graph in Comparative Example 1. In addition, as illustrated in Table 1, the area ratio of the trion in Comparative Example 2 was similar to the area ratio of the trion in Comparative Example 1. Further, a peak of an exciton graph in Comparative Example 2 became slightly lower than the peak of the exciton graph in Comparative Example 1. In addition, as illustrated in Table 1, the area ratio of the exciton in Comparative Example 2 was similar to the area ratio of the exciton in Comparative Example 1. In this regard, when the alumina is formed on the semiconductor layer by the ALD method using water as a reactant gas, an electron doping phenomenon may not occur in the MoS₂. Accordingly, when the alumina is formed on the semiconductor layer using water, an element characteristic of the semiconductor element of Comparative Example 2 became relatively lower than the element characteristic of the semiconductor element of Example, as illustrated in FIG. 10D.

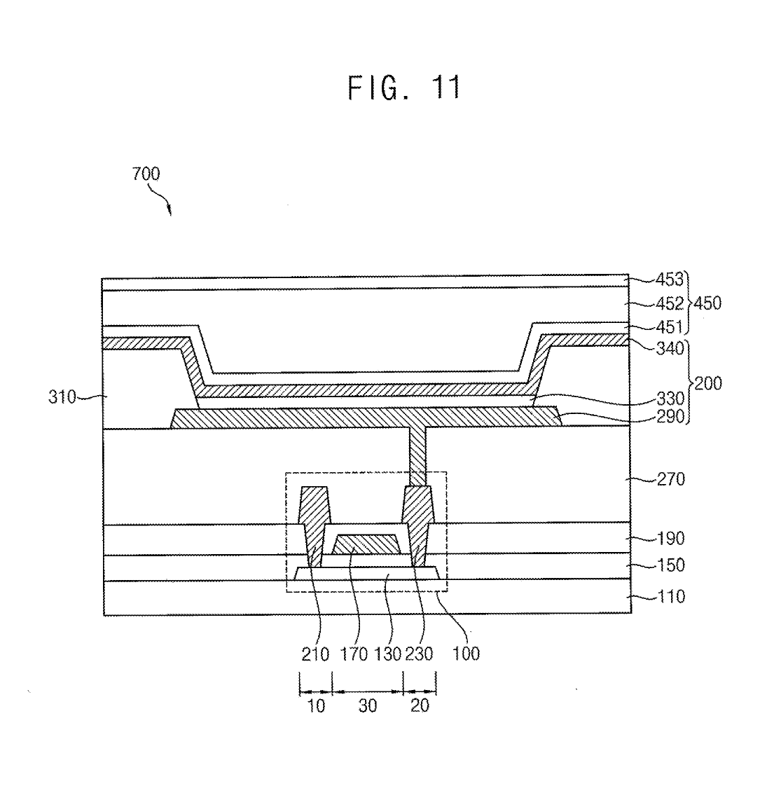

FIG. 11 is a cross-sectional view illustrating an organic light emitting display (OLED) device in accordance with example embodiments. An OLED device 700 illustrated in FIG. 11 may have a configuration including a semiconductor element 100 described with reference to FIG. 1. In FIG. 11, detailed descriptions for elements, which are substantially the same as or similar to the elements described with reference to FIG. 1, may not be repeated.

Referring to FIG. 11, an OLED device 700 may include a substrate 110, a semiconductor element 100, a planarization layer 270, a pixel defining layer 310, a pixel structure 200, and a thin film encapsulation (TFE) structure 450. Here, the semiconductor element 100 may include a semiconductor layer 130, a high-k insulating layer 150, a gate electrode 170, an insulating interlayer 190, a source electrode 210, and drain electrode 230, and the pixel structure 200 may include a lower electrode 290, a light emitting layer 330, and an upper electrode 340. In addition, the TFE structure 450 may include first TFE layer 451, a second TFE layer 452, and a third TFE layer 453.

Since the OLED device 700 includes the flexible substrate 110 and the TFE structure 450 having a flexibility, the OLED device 700 may serve as a flexible OLED device.

The substrate 110 may include transparent materials and/or opaque materials. The substrate 110 may have a source region 10, a drain region 20, and a channel region 30. The substrate 110 may include a flexible transparent material such as a flexible transparent resin substrate. The substrate 110 may have a structure in which a first organic layer, a first barrier film layer, a second organic layer, a second barrier film layer are sequentially stacked. The first and second barrier film layers may include inorganic materials, and the first and second organic layers may include organic materials. For example, each of the first and second barrier film layers may include silicon oxide, and may block water, moisture, etc. permeated through the first and second organic layers. Further, each of the first and second organic layers may include a polyimide-based resin.

Since the substrate 110 is relatively thin and flexible, the substrate 110 may be disposed on a rigid glass substrate to help support the formation of the semiconductor element 100 and the pixel structure 200. In a manufacturing process of the OLED device 700, after an insulating layer (e.g., a buffer layer) is provided on the second barrier film layer, the semiconductor element 100 and the pixel structure 200 may be disposed on the insulating layer. After the semiconductor element 100 and the pixel structure 200 are formed on the insulating layer, the rigid glass substrate on which the substrate 110 is disposed may be removed. It may be difficult to directly form the semiconductor element 100 and the pixel structure 200 on the substrate 110 because the substrate 110 is relatively thin and flexible. Accordingly, the semiconductor element 100 and the pixel structure 200 are formed on the substrate 110 and the rigid glass substrate, and then the first and second barrier film layers and the first and second organic layers may serve as the substrate 110 of the OLED device 700 after the removal of the rigid glass substrate.

A buffer layer may be disposed on the substrate 110. The buffer layer may be disposed on the entire substrate 110. The buffer layer may prevent the diffusion of metal atoms and/or impurities from the substrate 110 into the semiconductor element 100 (or may reduce a likelihood or degree of such diffusion). In addition, the buffer layer may improve a surface flatness (e.g., surface smoothness) of the substrate 110 when a surface of the substrate 110 is relatively irregular (e.g., rough). For example, the buffer layer may include a silicon compound, a metal oxide, etc.

The semiconductor layer 130 may be disposed in the source region 10, the drain region 20, and the channel region 30 on the substrate 110. In example embodiments, the semiconductor layer 130 may include a semiconductor layer having a 2DLS. The semiconductor layer having the 2DLS may include TMDC, graphene, etc. For example, the semiconductor layer having the 2DLS may consist essentially of MoS₂. In example embodiments, the semiconductor layer 130 may not include a Mo—O bond and a S—O bond.

The high-k insulating layer 150 may be disposed on the semiconductor layer 130. The high-k insulating layer 150 may cover the semiconductor layer 130 on the substrate 110, and may be disposed on the entire substrate 110. For example, the high-k insulating layer 150 may suitably or sufficiently cover the semiconductor layer 130 on the substrate 110, and may have a substantially level surface without a step (e.g., a step defect) around the semiconductor layer 130. In some embodiments, the high-k insulating layer 150 may cover the semiconductor layer 130 on the substrate 110, and may be disposed to a substantially uniform thickness along a profile of the semiconductor layer 130. In example embodiments, the high-k insulating layer 150 may be formed by ALD method, and a TMA as a precursor and an IPA as a reactant gas may be used in the ALD method. In other words, the IPA may be used as a reactant gas in the ALD method according to example embodiments, and thus ozone, oxygen, water, etc. may not be used as a reactant gas. For example, the IPA having a relatively low oxidizing power and a relatively large molecular size may be used as an oxidizing agent without using the oxidizing agent having a high oxidizing power such as ozone, oxygen, water, etc. Accordingly, the semiconductor layer 130 may not be damaged by an oxygen bond in a process for forming the high-k insulating layer 150. In addition, when the high-k insulating layer 150 is formed on the semiconductor layer 130 by the ALD method using the IPA, an electron doping phenomenon may be generated in the semiconductor layer 130. Accordingly, an element characteristic of the semiconductor element 100 may be increased by about 100 to 1000 times. The high-k insulating layer 150 may include materials where dielectric constant K is more than 8. In example embodiments, the high-k insulating layer 150 may include consist essentially of Al₂O₃.

The gate electrode 170 may be disposed in the channel region 30 on the high-k insulating layer 150. The gate electrode 170 may include a metal, a metal alloy, a metal nitride, a conductive metal oxide, transparent conductive materials, etc. These may be used alone or in a suitable combination thereof. In some example embodiments, the gate electrode 170 may have a multi-layered structure.

The insulating interlayer 190 may be disposed on the gate electrode 170. In some embodiments, the insulating interlayer 190 may cover the gate electrode 170 on the high-k insulating layer 150, and may be disposed on the entire high-k insulating layer 150. The insulating interlayer 190 may include a silicon compound, a metal oxide, etc.

The source electrode 210 and the drain electrode 230 may be disposed on the insulating interlayer 190. The source electrode 210 may be in direct contact (e.g., physical contact) with the source region 10 of the semiconductor layer 130 via a contact hole formed by removing a portion of the high-k insulating layer 150 and the insulating interlayer 190. The drain electrode 230 may be in direct contact (e.g., physical contact) with the drain region 20 of the semiconductor layer 130 via a contact hole formed by removing another portion of the high-k insulating layer 150 and the insulating interlayer 190. Each of the source electrode 210 and the drain electrode 230 may include a metal, an alloy, a metal nitride, a conductive metal oxide, transparent conductive materials, etc.

These may be used alone or in a suitable combination thereof. In some example embodiments, each of the source and drain electrodes 210 and 230 may have a multi-layered structure. Accordingly, the semiconductor element 100 including the semiconductor layer 130, the high-k insulating layer 150, the gate electrode 170, the insulating interlayer 190, the source electrode 210, and the drain electrode 230 may be disposed.

In example embodiments, the semiconductor element 100 has a top gate structure, but the present disclosure is limited thereto. For example, in some example embodiments, the semiconductor element 100 may have a bottom gate structure or a double gate structure.

The planarization layer 270 may be disposed on the source electrode 210, the drain electrode 230, and the insulating interlayer 190. The planarization layer 270 may cover the source electrode 210 and the drain electrode 230 on the insulating interlayer 190. For example, the planarization layer 270 may be disposed to have a high thickness to suitably or sufficiently cover the source and drain electrodes 210 and 230. In this case, the planarization layer 270 may have a substantially flat upper surface, and a planarization process may be further performed on the planarization layer 270 to implement the flat upper surface of the planarization layer 270. In some embodiments, the planarization layer 270 may cover the source and drain electrodes 210 and 230, and may be disposed to a substantially uniform thickness along a profile of the source and drain electrodes 210 and 230. The planarization layer 270 may include organic materials or inorganic materials. In example embodiments, the planarization layer 270 may include organic materials. For example, the planarization layer 270 may include polyimide, epoxy-based resin, acryl-based resin, polyester, photoresist, polyacryl-based resin, polyimide-based resin, a polyamide-based resin, a siloxane-based resin, etc.

The lower electrode 290 may be disposed on the planarization layer 270. The lower electrode 290 may be in contact with the drain electrode 230 via a contact hole formed by removing a portion of the planarization layer 270. In addition, the lower electrode 290 may be electrically coupled to (e.g., electrically connected to) the semiconductor element 100. The lower electrode 290 may include a metal, a metal alloy, a metal nitride, a conductive metal oxide, transparent conductive materials, etc. These may be used alone or in a suitable combination thereof. In some example embodiments, the lower electrode 290 may have a multi-layered structure.

The pixel defining layer 310 may be disposed on the planarization layer 270, and may expose a portion of the lower electrode 290. In other words, the pixel defining layer 310 may cover both lateral portions of the lower electrode 290. The pixel defining layer 310 may include organic materials or inorganic materials. In example embodiments, the pixel defining layer 310 may include organic materials.

The light emitting layer 330 may be disposed on the lower electrode 290 that is exposed by the pixel defining layer 310. The light emitting layer 330 may be formed using at least one of light emitting materials capable of generating different colors of light (e.g., a red color of light, a blue color of light, and/or a green color of light, etc) according to sub-pixels. In some embodiments, the light emitting layer 330 may generally generate a white color of light by stacking a plurality of light emitting materials capable of generating different colors of light such as a red color of light, a green color of light, a blue color of light, etc. In this case, a color filter may be disposed on the light emitting layer 330. The color filter may include at least one selected from a red color filter, a green color filter, and a blue color filter. In some embodiments, the color filter may include a yellow color filter, a cyan color filter, and a magenta color filter. The color filter may include a photosensitive resin (or color photoresist), etc.

The upper electrode 340 may be disposed on the pixel defining layer 310 and the light emitting layer 330. The upper electrode 340 may include a metal, a metal alloy, a metal nitride, a conductive metal oxide, transparent conductive materials, etc. These may be used alone or in a suitable combination thereof. In some example embodiments, the upper electrode 340 may have a multi-layered structure. Accordingly, the pixel structure 200 including the lower electrode 290, the light emitting layer 330, and the upper electrode 340 may be disposed.

The TFE structure 450 may be disposed on the upper electrode 340. For example, the second TFE layer 452 may be disposed on the first TFE layer 451, and the third TFE layer 453 may be disposed on the second TFE layer 452.

The first TFE layer 451 may be disposed on the upper electrode 340. The first TFE layer 451 may cover the upper electrode 340, and may be disposed to a substantially uniform thickness along a profile of the upper electrode 340. The first TFE layer 451 may prevent the pixel structure 200 from being deteriorated by the permeation of moisture, water, oxygen, etc. (or may reduce a likelihood or degree of such deterioration). In addition, the first TFE layer 451 may protect the pixel structure 200 from external impacts. The first TFE layer 451 may include inorganic materials.

The second TFE layer 452 may be disposed on the first TFE layer 451. The second TFE layer 452 may improve the flatness (e.g., surface smoothness) of the OLED device 700, and may protect the pixel structure 200. The second TFE layer 452 may include organic materials.

The third TFE layer 453 may be disposed on the second TFE layer 452. The third TFE layer 453 may cover the second TFE layer 452, and may be disposed to a substantially uniform thickness along a profile of the second TFE layer 452. The third TFE layer 453 together with the first TFE layer 451 and the second TFE layer 452 may prevent the pixel structure 200 from being deteriorated by the permeation of moisture, water, oxygen, etc. (or may reduce a likelihood or degree of such deterioration). In addition, the third TFE layer 453 together with the first TFE layer 451 and the second TFE layer 452 may protect the pixel structure 200 from external impacts. The third TFE layer 453 may include inorganic materials.

In some embodiments, the TFE structure 450 may have a five layer structure where the first to fifth TFE layers are stacked or a seven layer structure where the first to seventh TFE layers are stacked.

In the ALD process for forming the high-k insulating layer 150 in accordance with example embodiments, as the IPA is used as the reactant gas, the semiconductor layer 130 included in the OLED device 700 may not be damaged by oxygen bond. In addition, since the electron doping phenomenon occurs in the semiconductor layer 130, the element characteristic of the semiconductor element 100 may be increased. Further, since the OLED device 700 includes the semiconductor layer 130 that is readily bent and has a rigid characteristic, the OLED device 700 may serve as a flexible OLED device including the semiconductor element 100 having relatively high characteristics.

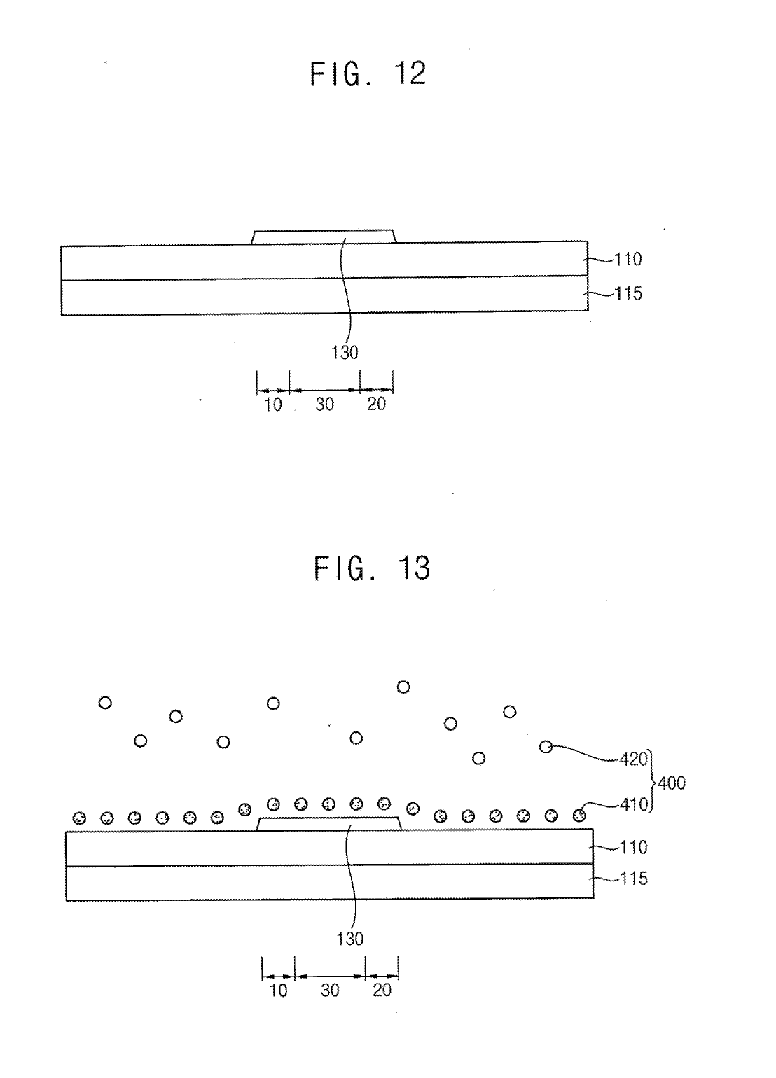

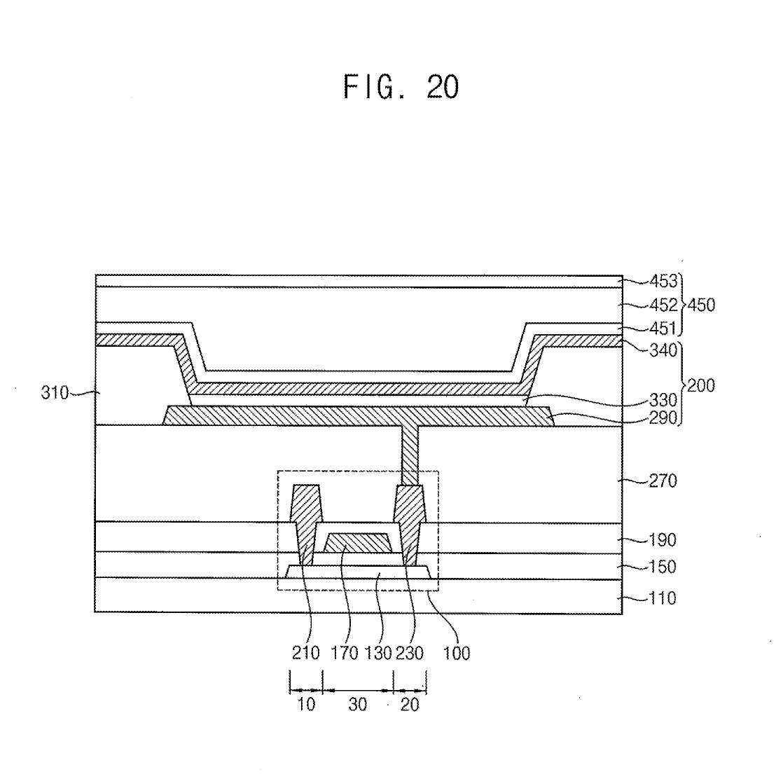

FIGS. 12, 13, 14, 15, 16, 17, 18, 19 and 20 are cross-sectional views illustrating a method of manufacturing an OLED device in accordance with example embodiments.

Referring to FIG. 12, a rigid glass substrate 115 may be provided. A substrate 110 including transparent materials and/or opaque materials may be formed on the rigid glass substrate 115. The substrate 110 may be formed using a flexible transparent material such as a flexible transparent resin substrate. In example embodiments, the substrate 110 may have a structure in which a first organic layer, a first barrier film layer, a second organic layer, a second barrier film layer are sequentially stacked. The first and second barrier film layers may be formed using inorganic materials, and the first and second organic layers may be formed using organic materials. For example, each of the first and second barrier film layers may include silicon oxide, and may block water, moisture, etc. permeated through the first and second organic layers. Further, each of the first and second organic layers may include a polyimide-based resin.

A buffer layer may be formed on the substrate 110. The buffer layer may be formed on the entire substrate 110. The buffer layer may prevent the diffusion of metal atoms and/or impurities from the substrate 110 into a semiconductor element (or may reduce a likelihood or degree of such diffusion). In addition, the buffer layer may improve a surface flatness (e.g., surface smoothness) of the substrate 110 when a surface of the substrate 110 is relatively irregular (e.g., rough). According to a type (e.g., composition) of the substrate 110, at least two buffer layers may be provided on the substrate 110, or the buffer layer may not be disposed (e.g., the buffer layer may be omitted). For example, the buffer layer may be formed using a silicon compound, a metal oxide, etc.

A semiconductor layer 130 may be formed in a source region 10, a drain region 20, and a channel region 30 on the substrate 110. In example embodiments, the semiconductor layer 130 may be formed using a semiconductor layer having a 2DLS. The semiconductor layer having the 2DLS may consist essentially of TMDC, graphene, etc. In example embodiments, the semiconductor layer 130 may include one selected from the group consisting of MoS₂, MoSe₂, MoTe₂, WS₂, WSe₂, WTe₂, ZrS₂, ZrSe₂, hBN graphene, BCN graphene, etc. For example, the semiconductor layer 130 may consist essentially of MoS₂.

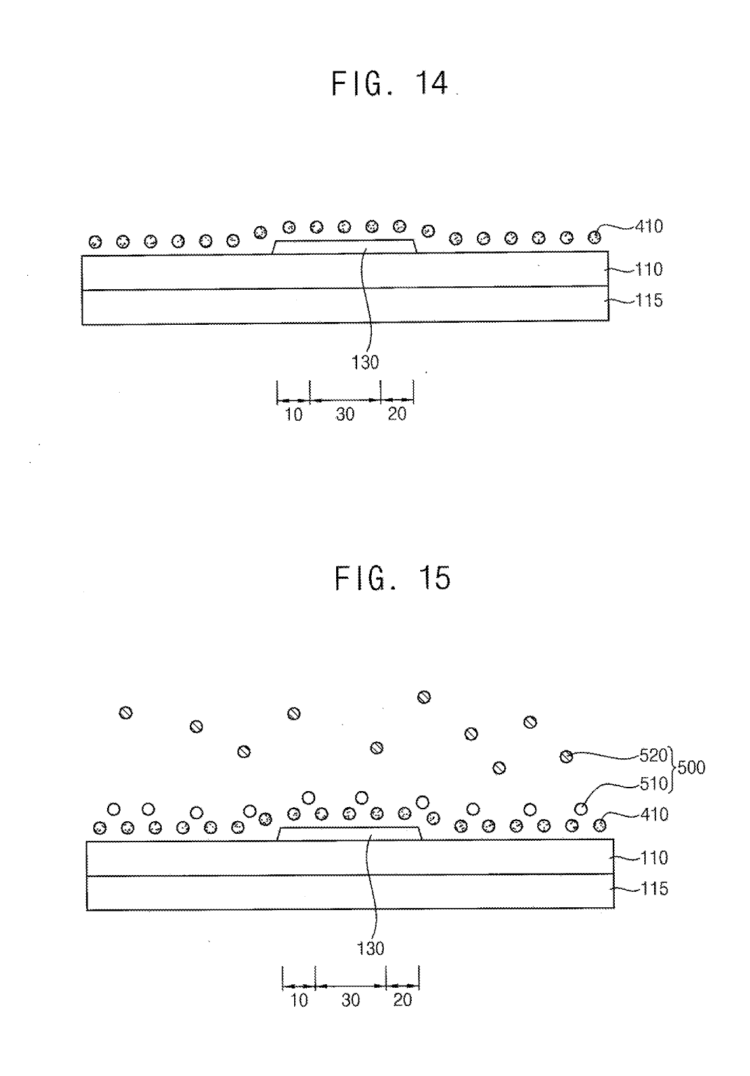

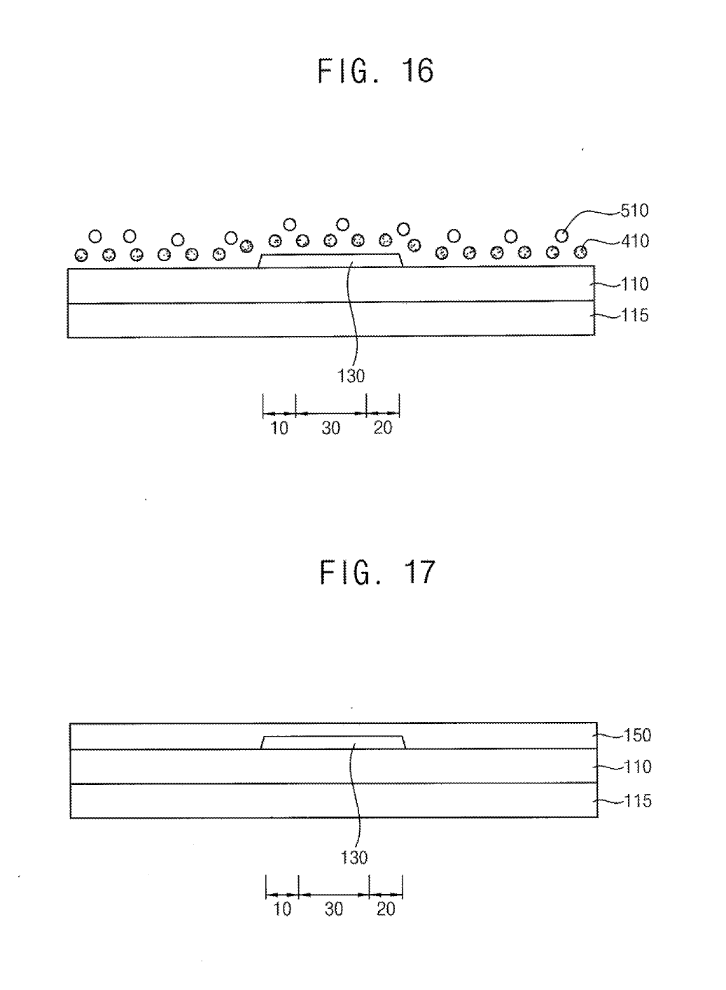

Referring to FIGS. 13, 14, 15, 16, and 17, a high-k insulating layer 150 may be formed by an ALD method. In example embodiments, a TMA as a precursor and an IPA as a reactant gas may be used in the ALD method. For example, FIG. 13 is a cross-sectional view illustrating an active act of injecting a precursor, and FIG. 14 is a cross-sectional view illustrating an active act of injecting a first purge gas. In addition, FIG. 15 is a cross-sectional view illustrating an active act of injecting a reactant gas, and FIG. 16 is a cross-sectional view illustrating an active act of injecting a second purge gas. Further, FIG. 17 is a cross-sectional view illustrating the high-k insulating layer 150 that is formed on the substrate 110.

Referring again to FIG. 13, a TMA gas 400 may be injected in a chamber such that atoms included in the TMA gas 400 are adsorbed on the substrate 110 and the semiconductor layer 130. For example, a plasma treatment process may be performed by using the TMA gas 400. In this case, the compounds or atoms included in the TMA gas 400 may be adsorbed to each other, or may be adsorbed on the substrate 110 and the semiconductor layer 130. For example, as the adsorption between the compounds or atoms is a physisorption, a bonding force between the compounds or atoms may be weak. On the other hand, as the adsorption where the compounds or atoms are adsorbed on the substrate 110 and the semiconductor layer 130 is a chemisorption, a bonding force between the compounds or atoms may be strong.

The TMA gas 400 may include a first TMA compound (or atom thereof) 410 and a second TMA compound (or atom thereof) 420. The first TMA compounds (or atoms thereof) 410 may be adsorbed on the substrate 110 and the semiconductor layer 130 in the chamber, and the second TMA compounds (or atoms thereof) 420 may be adsorbed to each other in the chamber or may be present alone in the chamber.

Referring again to FIG. 14, a first purge gas may be injected after the TMA gas 400 is injected. When the first purge gas is injected, the second TMA compounds (or atoms thereof) 420 may be removed from the chamber, and the first TMA compounds (or atoms thereof) 410 may remain on the substrate 110 and the semiconductor layer 130. The first purge gas may include Ar, N₂, etc.

Referring again to FIG. 15, an IPA gas 500 may be injected in the chamber such that IPA compounds (or atoms thereof) included in the IPA gas 500 and the first TMA compound (or atom thereof) 410 that is adsorbed on the substrate 110 and the semiconductor layer 130 are reacted after the first purge gas is injected. For example, a plasma treatment process may be performed by using the IPA gas 500. The IPA gas 500 may include a first IPA compound (or atom thereof) 510 and a second IPA compound (or atom thereof) 520. The first IPA compounds (or atoms thereof) 510 may be combined with (or bonded to) the first TMA compounds (or atoms thereof) 410. In this case, Al₂O₃ may be formed. The second IPA compounds (or atoms thereof) 520 may be adsorbed to each other in the chamber or may be present alone in the chamber.

For example, in a general ALD method, ozone, oxygen, water, etc. may be used as a reactant gas, and a semiconductor layer having the 2DLS may be bonded to oxygen in a process for injecting the reactant gas. In this case, when atoms of the semiconductor layer having the 2DLS are bonded to oxygen, the semiconductor layer having the 2DLS may be oxidized and may be significantly damaged by the high-k insulating layer. A method of manufacturing an OLED device according to example embodiments, the IPA gas 500 may be used as the reactant gas such that the IPA compounds (or atoms thereof) that are included in the IPA gas 500 are reacted with the first TMA compounds (or atoms thereof) 410 that are adsorbed on the substrate 110 and the semiconductor layer 130. Accordingly, the semiconductor layer 130 may not be damaged by an oxygen bond. In addition, when the Al₂O₃ is formed on the semiconductor layer 130 by the ALD method using the IPA gas 500 as the reactant gas, an electron doping phenomenon may be generated in MoS₂ of the semiconductor layer 130. Accordingly, the element characteristic of a semiconductor element may be increased.

Referring again to FIG. 16, a second purge gas may be injected after the IPA gas 500 is injected. When the second purge gas is injected, the second IPA compounds (or atoms thereof) 520 may be removed from the chamber, and the first IPA compounds (or atoms thereof) 510 combined with the first TMA compound (or atom thereof) 410 may remain. The second purge gas may include Ar, N₂, etc. Accordingly, one alumina layer having a high dielectric constant may be formed, and a high-k insulating layer 150 illustrated in FIG. 17 may be formed on the substrate 110 and the 130 by repeating processes illustrated in FIGS. 13, 14, 15, and 16. In example embodiments, the high-k insulating layer 150 may include materials where dielectric constant K is more than 8.

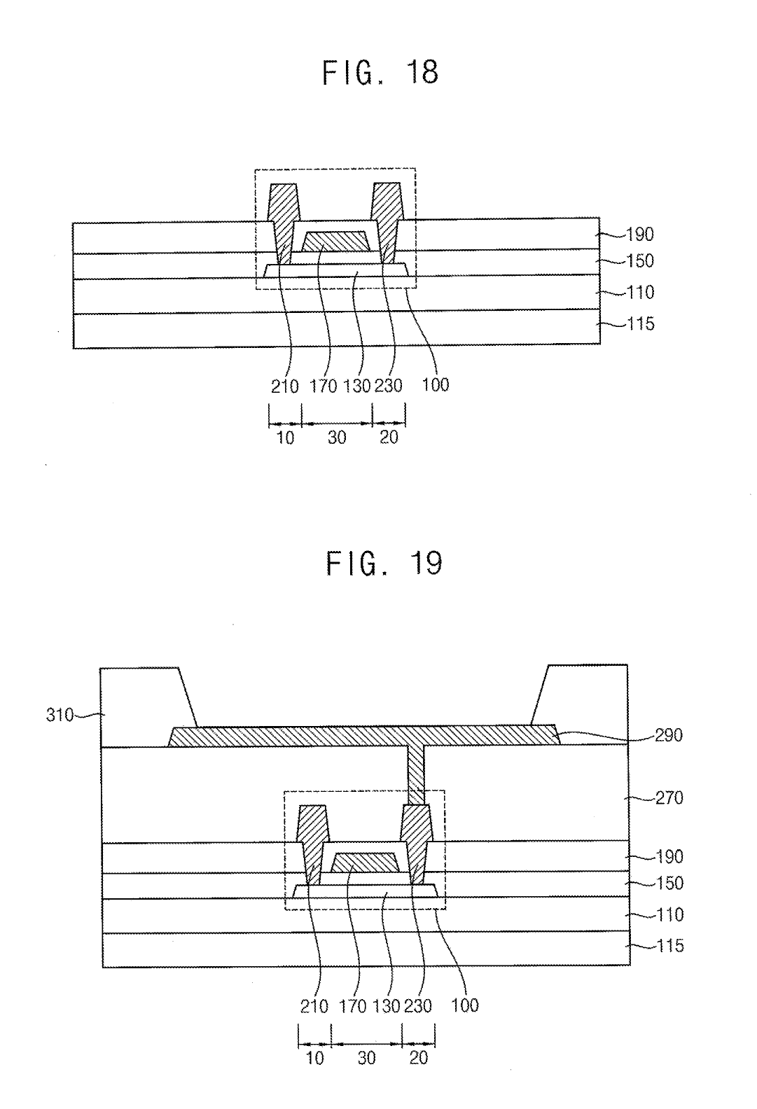

Referring to FIG. 18, a gate electrode 170 may be formed in the channel region 30 on the high-k insulating layer 150. The gate electrode 170 may be formed using a metal, a metal alloy, a metal nitride, a conductive metal oxide, transparent conductive materials, etc. For example, the gate electrode 170 may include Au, Ag, Al, Pt, Ni, Ti, Pd, Mg, Ca, Li, Cr, Ta, W, Cu, Mo, Sc, Nd, Ir, an alloy of aluminum, AINx, an alloy of silver, WNx, an alloy of copper, an alloy of molybdenum, TiNx, CrNx, TaNx, SRO, ZnOx, ITO, SnOx, InOx, GaOx, IZO, etc. These may be used alone or in a suitable combination thereof. In some example embodiments, the gate electrode 170 may have a multi-layered structure.

An insulating interlayer 190 may be formed on the gate electrode 170. The insulating interlayer 190 may cover the gate electrode 170 on the high-k insulating layer 150, and may be formed on the entire high-k insulating layer 150. The insulating interlayer 190 may be formed using a silicon compound, a metal oxide, etc. For example, the insulating interlayer 190 may include SiOx, SiNx, SiOxNy, SiOxCy, SiCxNy, AlOx, AINx, TaOx, HfOx, ZrOx, TiOx, etc.

A source electrode 210 and a drain electrode 230 may be formed on the insulating interlayer 190. The source electrode 210 may be in direct contact (e.g., physical contact) with the source region 10 of the semiconductor layer 130 via a contact hole formed by removing a portion of the high-k insulating layer 150 and the insulating interlayer 190. The drain electrode 230 may be in direct contact (e.g., physical contact) with the drain region 20 of the semiconductor layer 130 via a contact hole formed by removing another portion of the high-k insulating layer 150 and the insulating interlayer 190. Each of the source electrode 210 and the drain electrode 230 may be formed using a metal, an alloy, a metal nitride, a conductive metal oxide, transparent conductive materials, etc. These may be used alone or in a suitable combination thereof. In some example embodiments, each of the source and drain electrodes 210 and 230 may have a multi-layered structure. Accordingly, a semiconductor element 100 including the semiconductor layer 130, the high-k insulating layer 150, the gate electrode 170, the insulating interlayer 190, the source electrode 210, and the drain electrode 230 may be formed.

Referring to FIG. 19, a planarization layer 270 may be formed on the source electrode 210, the drain electrode 230, and the insulating interlayer 190. The planarization layer 270 may cover the source electrode 210 and the drain electrode 230 on the insulating interlayer 190. For example, the planarization layer 270 may be formed to have a high thickness to suitably or sufficiently cover the source and drain electrodes 210 and 230. In this case, the planarization layer 270 may have a substantially flat upper surface, and a planarization process may be further performed on the planarization layer 270 to implement the flat upper surface of the planarization layer 270. In some embodiments, the planarization layer 270 may cover the source and drain electrodes 210 and 230, and may be disposed to a substantially uniform thickness along a profile of the source and drain electrodes 210 and 230. The planarization layer 270 may include organic materials or inorganic materials. In example embodiments, the planarization layer 270 may be formed using organic materials such as polyimide, epoxy-based resin, acryl-based resin, polyester, photoresist, polyacryl-based resin, polyimide-based resin, a polyamide-based resin, a siloxane-based resin, etc.

A lower electrode 290 may be formed on the planarization layer 270. The lower electrode 290 may be in contact with the drain electrode 230 via a contact hole formed by removing a portion of the planarization layer 270. In addition, the lower electrode 290 may be electrically coupled to (e.g., electrically connected to) the semiconductor element 100. The lower electrode 290 may be formed using a metal, a metal alloy, a metal nitride, a conductive metal oxide, transparent conductive materials, etc. These may be used alone or in a suitable combination thereof. In some example embodiments, the lower electrode 290 may have a multi-layered structure.

A pixel defining layer 310 may be formed on the planarization layer 270, and may expose a portion of the lower electrode 290. In other words, the pixel defining layer 310 may cover both lateral portions of the lower electrode 290. The pixel defining layer 310 may include organic materials or inorganic materials. In example embodiments, the pixel defining layer 310 may be formed using organic materials.

A light emitting layer 330 may be formed on the lower electrode 290 that is exposed by the pixel defining layer 310. The light emitting layer 330 may be formed using at least one of light emitting materials capable of generating different colors of light (e.g., a red color of light, a blue color of light, and a green color of light, etc) according to sub-pixels. In some embodiments, the light emitting layer 330 may generally generate a white color of light by stacking a plurality of light emitting materials capable of generating different colors of light such as a red color of light, a green color of light, a blue color of light, etc. In this case, a color filter may be disposed on the light emitting layer 330. The color filter may include at least one selected from a red color filter, a green color filter, and/or a blue color filter. In some embodiments, the color filter may include a yellow color filter, a cyan color filter, and/or a magenta color filter. The color filter may be formed using a photosensitive resin (or color photoresist), etc.

An upper electrode 340 may be formed on the pixel defining layer 310 and the light emitting layer 330. The upper electrode 340 may be formed using a metal, a metal alloy, a metal nitride, a conductive metal oxide, transparent conductive materials, etc. These may be used alone or in a suitable combination thereof. In some example embodiments, the upper electrode 340 may have a multi-layered structure. Accordingly, a pixel structure 200 including the lower electrode 290, the light emitting layer 330, and the upper electrode 340 may be formed.

A first TFE layer 451 may be formed on the upper electrode 340. The first TFE layer 451 may cover the upper electrode 340, and may be formed to a substantially uniform thickness along a profile of the upper electrode 340. The first TFE layer 451 may prevent the pixel structure 200 from being deteriorated by the permeation of moisture, water, oxygen, etc. (or may reduce a likelihood or degree of such deterioration). In addition, the first TFE layer 451 may protect the pixel structure 200 from external impacts. The first TFE layer 451 may be formed using inorganic materials.

A second TFE layer 452 may be formed on the first TFE layer 451. The second TFE layer 452 may improve the flatness (e.g., surface smoothness) of an OLED device, and may protect the pixel structure 200. The second TFE layer 452 may be formed using organic materials.

A third TFE layer 453 may be formed on the second TFE layer 452. The third TFE layer 453 may cover the second TFE layer 452, and may be formed to a substantially uniform thickness along a profile of the second TFE layer 452. The third TFE layer 453 together with the first TFE layer 451 and the second TFE layer 452 may prevent the pixel structure 200 from being deteriorated by the permeation of moisture, water, oxygen, etc. (or may reduce a likelihood or degree of such deterioration). In addition, the third TFE layer 453 together with the first TFE layer 451 and the second TFE layer 452 may protect the pixel structure 200 from external impacts. The third TFE layer 453 may be formed using inorganic materials. Accordingly, a TFE structure 450 including the first TFE layer 451, the second TFE layer 452, and the third TFE layer 453 may be formed. In some embodiments, the TFE structure 450 may have a five layer structure where first to fifth TFE layers are stacked or a seven layer structure where the first to seventh TFE layers are stacked. The rigid glass substrate 115 may be separated from the substrate 110 after the TFE structure 450 is formed.

Accordingly, an OLED device 700 illustrated in FIG. 11 may be manufactured. In a method of manufacturing an OLED device according to example embodiments, as the IPA as a reactant gas is used in the ALD process for forming the high-k insulating layer 150, the semiconductor layer 130 included in the OLED device may not be damaged by the oxygen bond. In addition, since the electron doping phenomenon is generated in MoS₂ of the semiconductor layer 130, the element characteristic of a semiconductor element may be increased. Further, since the OLED device includes the semiconductor layer 130 that is readily bent and has a rigid characteristic, the OLED device may serve as a flexible OLED device including the semiconductor element 100 having relatively high characteristics.

Embodiments of the present disclosure may be applied to various suitable display devices including an organic light emitting display device. For example, embodiments of the present disclosure may be applied to vehicle-display device, a ship-display device, an aircraft-display device, portable communication devices, display devices for display or for information transfer, a medical-display device, etc.

As used herein, the term “consisting essentially of” means that any components in addition to those recited will not materially affect the chemical, physical, optical and/or electrical properties of the recited feature. For example, the high-k insulating layer consisting essentially of alumina (Al₂O₃) may include impurities generally associated therewith, as well as additional components that do not materially affect the chemical, physical, optical and/or electrical properties of the high-k insulating layer. Similarly, the semiconductor layer consisting essentially of MoS2 may include impurities generally associated therewith, as well as additional components that do not materially affect the chemical, physical, optical and/or electrical properties of the semiconductor layer.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, acts, operations, elements, and/or components, but do not preclude the presence or addition of one or more other features, integers, acts, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The foregoing is illustrative of example embodiments and is not to be construed as limiting thereof. Although a few example embodiments have been described, those skilled in the art will readily appreciate that many modifications are possible in the example embodiments without materially departing from the novel features of the present disclosure. Accordingly, all such modifications are intended to be included within the scope of the present disclosure as defined in the appended claims.

Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims, and equivalents thereof.

What is claimed is:

1. A method of manufacturing a semiconductor element, the method comprising:
forming a semiconductor layer that has a two-dimensional layered structure on a substrate having a source region, a drain region, and a channel region;
forming a high dielectric constant (high-k) insulating layer on the semiconductor layer by atomic layer deposition (ALD) using tri-Methyl-aluminum (TMA) as a precursor and isopropyl alcohol (IPA) as a reactant gas;
forming a gate electrode in the channel region on the high-k insulating layer;
forming an insulating interlayer on the gate electrode; and
forming source and drain electrodes in the source and drain regions on the insulating interlayer.

2. The method of claim 1, wherein forming of the high-k insulating layer on the semiconductor layer by ALD using the TMA as the precursor and the IPA as the reactant gas comprises:
adsorbing aluminum atoms on the substrate by injecting a TMA gas;
injecting a first purge gas after the TMA gas is injected;
reacting the IPA and the aluminum atom that is adsorbed on the substrate by injecting an IPA gas after the first purge gas is injected; and
injecting a second purge gas after the IPA gas is injected.

3. The method of claim 2, wherein the high-k insulating layer consists essentially of alumina Al₂O₃.

4. The method of claim 1, wherein the high-k insulating layer comprises one selected from the group consisting of alumina (Al₂O₃), zirconium oxide (ZrO₂), and hafnium oxide (HfO₂).

5. The method of claim 1, wherein the semiconductor layer having the two-dimensional layered structure comprises transition metal dichalcogenide (TMDC) and graphene.

6. The method of claim 5, wherein the semiconductor layer having the two-dimensional layered structure comprises one selected from the group consisting of molybdenum disulfide (MoS₂), molybdenum diselenide (MoSe₂), molybdenum ditelluride (MoTe₂), tungsten disulfide (WS₂), tungsten diselenide (WSe₂), tungsten ditelluride (WTe₂), zirconium disulfide (ZrS₂), zirconium diselenide (ZrSe₂), and hexagonal boron nitride (hBN) graphene.

7. The method of claim 1, wherein the semiconductor layer having the two-dimensional layered structure consists essentially of molybdenum disulfide (MoS₂).

8. The method of claim 1, wherein the semiconductor layer does not include a molybdenum-oxygen (Mo—O) bond and a disulfide-oxygen (S—O) bond.

9. A method of manufacturing an organic light emitting display (OLED) device, the method comprising:
providing a substrate having a source region, a drain region, and a channel region;
forming a semiconductor element, wherein the forming of the semiconductor element comprises:
forming a semiconductor layer that has a two-dimensional layered structure in the source region, the drain region, and the channel region on the substrate;
forming a high dielectric constant (high-k) insulating layer on the semiconductor layer by atomic layer deposition (ALD) using tri-methyl-aluminum (TMA) as a precursor and isopropyl alcohol (IPA) as a reactant gas;
forming a gate electrode in the channel region on the high-k insulating layer;
forming an insulating interlayer on the gate electrode; and
forming source and drain electrodes in the source and drain regions on the insulating interlayer;
forming a pixel structure on the semiconductor layer; and
forming a thin film encapsulation (TFE) structure on the pixel structure.

10. The method of claim 9, wherein the forming of the pixel structure on the semiconductor layer comprises:
forming a lower electrode such that the lower electrode is electrically coupled to the drain electrode;
forming a light emitting layer on the lower electrode; and
forming an upper electrode on the light emitting layer.

11. The method of claim 10, wherein the forming of the thin film encapsulation structure on the pixel structure comprises:
forming a first TFE layer having inorganic materials on the upper electrode;
forming a second TFE layer having organic materials on the first TFE layer; and
forming a third TFE layer having inorganic materials on the second TFE layer.

12. The method of claim 9, wherein the substrate and the TFE structure comprise flexible materials.

13. The method of claim 9, wherein the forming of the high-k insulating layer on the semiconductor layer by ALD using the TMA as the precursor and the IPA as the reactant gas comprises:
adsorbing aluminum atoms on the substrate by injecting a TMA gas;
injecting a first purge gas after the TMA gas is injected;
reacting the IPA and the aluminum atom that is adsorbed on the substrate by injecting an IPA gas after the first purge gas is injected; and
injecting a second purge gas after the IPA gas is injected.

14. The method of claim 13, wherein the high-k insulating layer consists essentially of alumina Al₂O₃.

15. The method of claim 9, wherein the semiconductor layer having the two-dimensional layered structure consists essentially of molybdenum disulfide (MoS₂).

16. The method of claim 9, wherein the semiconductor layer does not include a molybdenum-oxygen (Mo—O) bond and a disulfide-oxygen (S—O) bond.

17. An organic light emitting display (OLED) device comprising:
a substrate having a source region, a drain region, and a channel region;
a semiconductor layer in the source region, the drain region, and the channel region on the substrate, the semiconductor layer consisting essentially of molybdenum disulfide (MoS₂);
a high dielectric constant (high-k) insulating layer covering the semiconductor layer on the substrate, the high-k insulating layer consisting essentially of alumina (Al₂O₃);
a gate electrode in the channel region on the high-k insulating layer;
an insulating interlayer covering the gate electrode on the high-k insulating layer;
source and drain electrodes in the source and drain regions on the insulating interlayer;
a pixel structure on the source and drain electrodes; and
a thin film encapsulation (TFE) structure on the pixel structure.

18. The OLED device of claim 17, wherein the semiconductor layer does not include a molybdenum-oxygen (Mo—O) bond and a disulfide-oxygen (S—O) bond.

19. The OLED device of claim 17, wherein the substrate and the TFE structure comprise flexible materials.
